(19) United States
(12) Patent Application Publication
(10) Pub. No.: US 2024/0407093 A1
(43) Pub. Date: Dec. 5, 2024

(54) INTRA-PAIR SKEW COMPENSATION OF DIFFERENTIAL SIGNALS

(71) Applicant: Achronix Semiconductor Corporation, SantaClara, CA (US)

(72) Inventors: Hansel Desmond Dsilva, Thane West (IN); Sasikala J, Chennai (IN); Amit Kumar, Bengaluru (IN)

(21) Appl. No.: 18/203,166

(22) Filed: May 30, 2023

(51) Int. Cl. H05K 1/11; H05K 3/10; H05K 3/40

(52) U.S. Cl. CPC H05K 1/115; H05K 3/10; H05K 3/4038

(57) ABSTRACT

If the two traces of a differential signal trace pair are not of identical length, intra-pair skew occurs as a result of the different flight time for the signal on each trace. Introducing serpentine routing into the shorter trace compensates for the intra-pair skew by increasing the effective length of the trace. However, the serpentine routing may also introduce impedance discontinuities. An impedance discontinuity leads to reflections and resonances, which hamper the transmitted signal in reaching the receiver. Adding extrusions to the serpentine routing may improve the impedance profile of the differential trace and thus lower reflections.

### FIELD OF THE INVENTION

The present application relates to differential signals in circuits and, more specifically, to intra-pair skew compensation of differential signals.

### BACKGROUND

High-speed signal transmission involves differential signaling consisting of a positive and negative signal conductor having a reference to ground. A differential signal pair consists of a positive trace and a negative trace. Intra-pair skew is the difference in the time of flight of the signal along the positive and negative, which may rise due to length mismatch within the differential pair or difference in material properties.

Multi-layer circuits use vertical interconnect accesses (VIAs) to communicate electrical signals between layers. A VIA typically comprises a conductive barrel that connects two layers and passes through any intervening layers. After the layers of the multi-layer circuit are printed (e.g., by etching), holes are drilled through the layers and the conductive barrel is placed in the hole. During printing, conductive traces connect to the location that the barrel will be placed on layers connecting to the VIA. On other layers, a cylindrical clearing around the VIAs is created, which provides insulation between the VIA and the metal on that layer. The conductive region surrounding a VIA on a connected layer is referred to as a pad; the non-conductive region surrounding a VIA on a layer, whether connected or unconnected, is referred to as an antipad. The holes may be plated with a conductive material (e.g., copper) that electrically connects the pads.

A differential VIA comprises two conductive barrels in separate holes. The signal carried on the differential VIA is determined by comparing the voltages of the two conductive barrels. By contrast, a standard VIA uses a single conductive barrel and the signal carried on the standard VIA is determined by comparing the voltage of the conductive barrel with ground.

Discontinuities in electrical connections, including discontinuities resulting from VIAs, result in signal loss when the operating frequency increases. Circuit designers compensate for this increased impedance by reducing the operating frequency or increasing the operating voltage, either of which increases the power consumption per operation of the resulting circuit. A differential signal transmitted through a multi-layer circuit travels mostly on the trace portion in the package and printed circuit board (PCB), but may also traverse one or more VIAs.

### BRIEF DESCRIPTION OF THE DRAWINGS

Some embodiments of the disclosed technology are illustrated by way of example and not limitation in the figures of the accompanying drawings.

FIG. 1 is a diagrammatic view of differential signal traces including serpentine sections with extrusions in a PCB, according to some example embodiments.

FIG. 2 is a diagrammatic view of differential signal traces including serpentine sections with extrusions in a cable, according to some example embodiments.

FIG. 3 is a diagrammatic cross-section view of a design of a multi-layer circuit including a differential VIA and ground connections, according to some example embodiments.

FIG. 4 depicts adding fins to a serpentine section of a differential signal trace, according to some example embodiments.

FIG. 5 depicts adding tabs to a serpentine section of a differential signal trace, according to some example embodiments.

FIG. 6 shows differences in impedance for two different designs of differential traces, according to some example embodiments.

FIG. 7 is a flowchart of a method of fabricating a circuit including a differential trace with a serpentine portion with extrusions, according to some example embodiments.

FIG. 8 is a block diagram illustrating components of a system for performing the methods described herein, according to some example embodiments.

### DETAILED DESCRIPTION

Example methods, systems, and circuits for fabricating a circuit including serpentine routing with extrusions are described. In the following description, numerous examples having example-specific details are set forth to provide an understanding of example embodiments. It will be evident, however, to one of ordinary skill in the art that these examples may be practiced without these example-specific details and/or with different combinations of the details than are given here. Thus, specific embodiments are given for the purpose of simplified explanation and not limitation.

By modifying the physical structures used to implement a circuit, the impedance of the circuit is altered without affecting the logic implemented by the circuit. Multiple designs may be simulated to determine impedance profiles of each design, allowing a circuit designer to select a design based on the impedance profiles. The impedance profile indicates the impedance of the circuit as a function of frequency, a function of time after a step function is applied, or both.

One feature that can be modified is the shape of a trace. If the two traces of a differential signal trace pair are not of identical length, intra-pair skew occurs as a result of the different flight time for the signal on each trace. Introducing serpentine routing into the shorter trace compensates for the intra-pair skew by increasing the effective length of the trace. A serpentine section of a trace comprises one or more serpentine curves. Each serpentine curve moves the trace from its original path for a short distance and then returns the trace to its original path.

However, the serpentine routing may also introduce impedance discontinuities. An impedance discontinuity leads to reflections and resonances, which hamper the transmitted signal in reaching the receiver. A smooth impedance profile translates to a resonance free insertion loss profile and thus helps in the overall interconnect performance from a reflection and loss perspective.

As used herein, the term “extrusion” refers to additional metal deposited within a serpentine curve that is connected to at least part of the interior of a serpentine curve but does not entirely fill the interior of the serpentine curve. A “tab” is an extrusion with a rectangular shape. A “fin” is an extrusion with a trapezoidal shape.

Adding extrusions to one or more of the serpentine curves of the serpentine section of a trace modifies the impedance properties of the differential pair. It is to be noted that the geometry presented may be applied to the trace portion in the layout of the printed circuit board, package, connector, or cable assembly and that the dimensions of the trace of a differential pair may vary for width and spacing depending on the material chosen as part of the stackup and component form factor.

By using these improved fabrication techniques to fabricate circuits in which differential signal traces have improved impedance profiles, circuit efficiency is improved. For example, the resulting circuit may operate at a reduced voltage or higher frequency than a similar circuit fabricated using traditional designs.

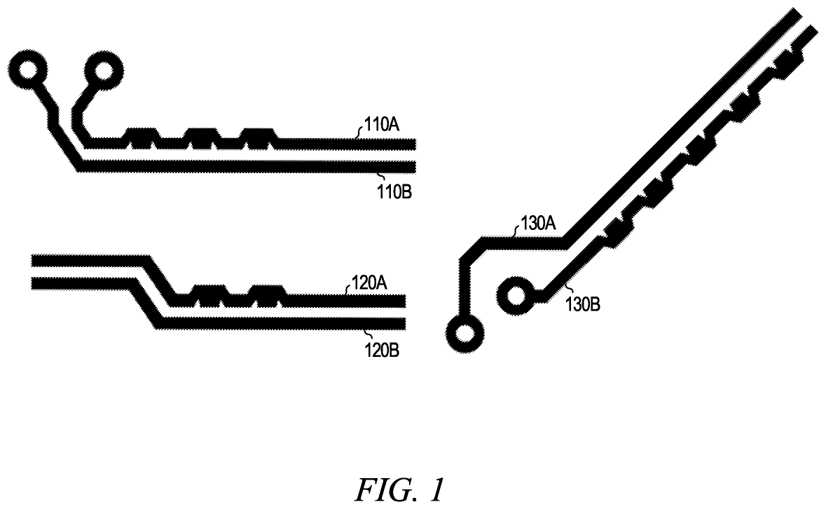

FIG. 1 is a diagrammatic view of differential signal traces including serpentine sections with extrusions in a PCB, according to some example embodiments. Three differential signal trace pairs are shown as 110A and 110B, 120A and 120B, and 130A and 130B. The differential signal trace pairs may be integrated into a PCB.

When the voltage on one trace is higher than the voltage on the other, a logical 1 signal is transmitted; when the other trace carries a higher voltage than the first trace, a logical 0 signal is transmitted. As the operating frequency increases, the amount of time at which the relative voltages are held decreases. At high enough frequencies, even very small differences in length between the two traces can cause the alignment of the signals to become skewed and introduce data transmission errors.

Accordingly, serpentine portions are added to the traces 110A, 120A, and 130B, adding length to those traces to compensate for a shorter path followed by the corresponding traces 110B, 120B, and 130A. Each serpentine portion includes one or more serpentine curves (e.g., three serpentine curves in the trace 110A, two serpentine curves in the trace 120A, and five serpentine curves in the trace 130B). However, every bend in the trace introduces impedance and reflection effects. No complex circuit can be formed of completely straight traces, so some bends, such as those in the traces 110B, 120B, and 130A may be unavoidable. Nonetheless, the added serpentine portions in the traces 110A, 120A, and 130B add a significant number of additional bends.

As disclosed herein, the addition of extrusions to each of the serpentine curves reduces the impedance discontinuities and reflections of the serpentine portions. In the examples of FIG. 1, the extrusions are fins.

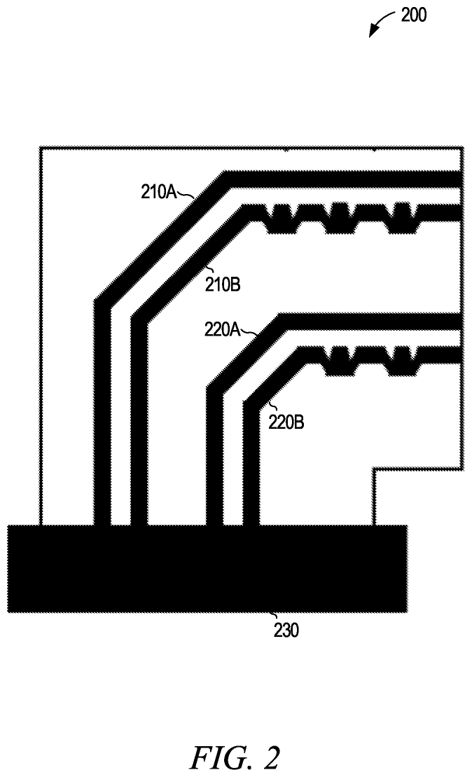

FIG. 2 is a diagrammatic view of differential signal traces including serpentine sections with extrusions in a cable 200, according to some example embodiments. Cable connector 230 may connect the cable 200 to a PCB. Two differential signal trace pairs are shown as a first pair 210A and 210B and a second pair 220A and 220B. For each pair, the trace on the inside of the turn follows a shorter path than the trace on the outside of the turn. Accordingly, a serpentine portion is added to the traces 210B and 220B. Extrusions in the form of fins are added to the traces 210B and 220B to reduce the impact on impedance discontinuities and reflections of the serpentine portions.

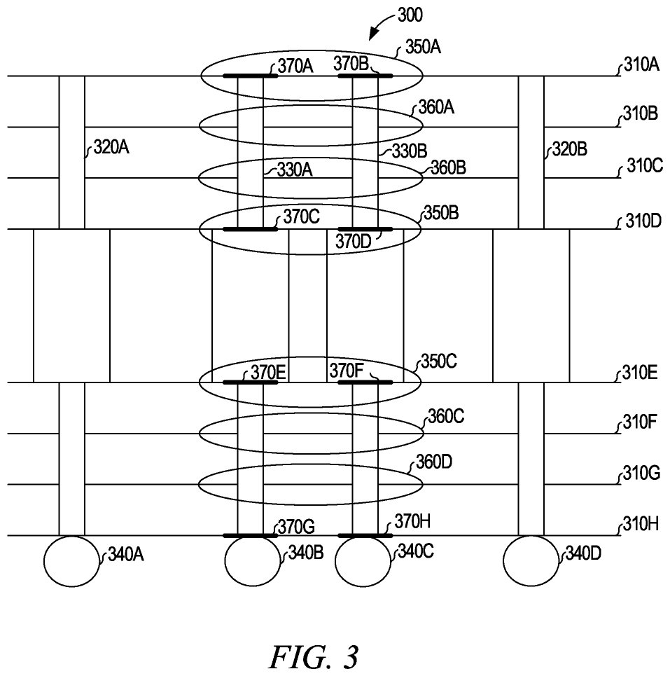

FIG. 3 is a diagrammatic cross-section view of a design of a multi-layer circuit 300 including a differential VIA and ground connections, according to some example embodiments. The multi-layer circuit 300 comprises circuit layers 310A, 310B, 310C, 310D, 310E, 310F, 310G, and 310H. The differential VIA includes VIA barrels 330A and 330B, antipads 350A, 350B, 350C, 360A, 360B, 360C, and 360D, and pads 370A, 370B, 370C, 370D, 370E, 370F, 370G, and 370H. External connections to the multi-layer circuit 300 are provided by balls 340A, 340B, 340C, and 340D.

The pads 370A-370H connect the conductive VIA barrels 330A-330B to circuit components on the layers 310A, 310D, 310E, and 310H. The pads 370A-370H may be circular or ovoid in shape, among other options. The presence, absence, size, and shape of the pad on each layer impacts the impedance of the differential VIA. Additionally, the distance between the VIA barrels 330A and 330B, the distance between the VIA barrels 330A-330B and the ground connections 320A-320B, or both may affect the impedance of the differential VIA. For example, reducing the distance between the two VIA barrels 330A and 330B may increase the capacitance of the differential VIA, noting that at least a minimum separation is required to avoid direct current flow between the two conductors.

The antipads 350A-360D (e.g., non-conductive voids) separate the conductive VIA barrels 330A-330B from unconnected circuit components. For clarity, the antipads 350A-360D are drawn in an isometric view, rather than in profile, since they would be nearly invisible in the true profile view. On layers 310A, 310D, and 310E, a single antipad surrounds both VIA barrels 330A and 330B. The selection of whether to use a single antipad or multiple antipads, surrounding each VIA barrel separately, on a layer impacts the impedance of the differential VIA. Additionally, the size of each antipad impacts the impedance of the differential VIA. Measuring the impedance of the differential VIA for each design (either in simulation or on an actual device) allows the circuit designer to select the circuit design that reduces signal reflections due to impedance discontinuities in ensuring the transmission of the signal with minimum noise.

A dielectric material separates each circuit layer. The thickness of the dielectric material is not necessarily the same between each pair of circuit layers. In the example shown in FIG. 3, the thickness of the dielectric material between the circuit layers 310D and 310E is greater than the thickness of the dielectric material between other pairs of adjacent circuit layers. In some example embodiments, every fourth dielectric material layer is thicker to provide greater structural stability to the finished multi-layer circuit.

The balls 340A-340D provide for external connections to the fabricated circuit. For example, the fabricated circuit may be a flip-chip ball grid array (FCBGA) chip and the balls 340A-340D of the FCBGA may be connected to a PCB using solder. An FCBGA chip may comprise a printed silicon die connected to a substrate that routes pin signals from the die to ball connections. The substrate acts as an adapter between the custom silicon die and a PCB that expects a predefined ball interface. Using different substrates, the same silicon die design can be used to create different PCBGAs for use with different PCBs. The substrate may be fabricated using a less-expensive process than the silicon die, resulting in efficiency gains over simply fabricating different monolithic chips.

The differential traces shown in FIG. 1 may be combined with the VIAs shown in FIG. 3 to create a three-dimensional circuit trace that transmits a differential signal within a layer using a differential trace and between layers using VIAs. Accordingly, VIA fabrication options (e.g., location, size of pads and antipads, and the like) may be selected to compensate for impedance introduced by the traces. Additionally, trace fabrication options, such as the use of serpentine portions with or without extrusions, may be selected to compensate for impedance introduced by a VIA.

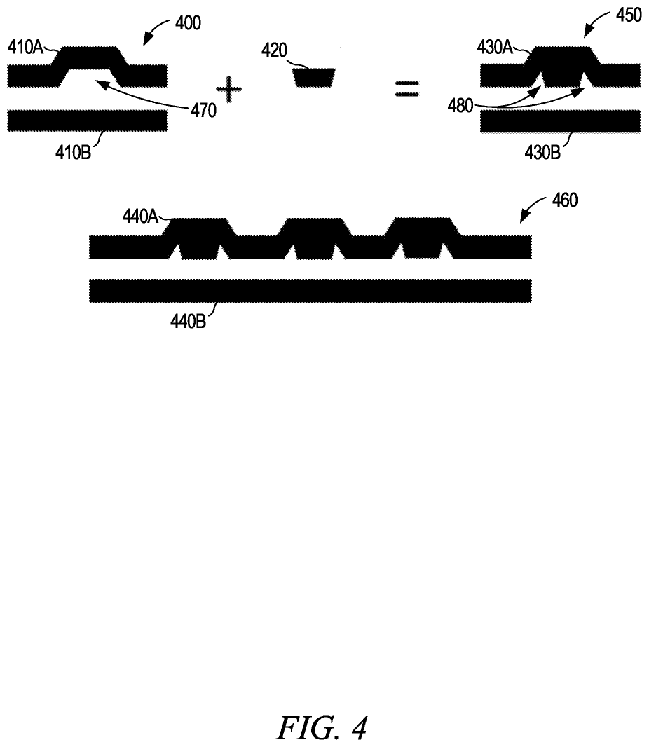

FIG. 4 depicts adding fins to a serpentine section of a differential signal trace 460, according to some example embodiments. The differential signal trace 400 comprises traces 410A and 410B. The differential signal trace 450 comprises traces 430A and 430B. The differential signal trace 460 comprises traces 440A and 440B.

The trace 410A comprises a single serpentine curve with interior 470. A fin 420 may be added to the interior of the serpentine curve to form the serpentine curve with a fin extrusion of the trace 430A. The conductive path between the opposite sides of the serpentine curve is not shortened because of the presence of cutouts 480. The trace 440A includes a serpentine section with three serpentine curves. Each of the three serpentine curves of the trace 440A includes a fin extrusion. By virtue of the addition of the fin 420 to the interiors of the serpentine curves of the serpentine section of the trace 440A, the electrical properties, including impedance discontinuities and reflections, of the differential signal trace 460 are modified.

The width of the trace 410B and the width of the trace 410A may be equal (e.g., 4.7 mils). The intra-pair spacing may be less than the width of the traces 410A and 410B (e.g., 4.0 mils). Each serpentine curve may include a first segment at a 45 degree angle from the path of the trace, a second segment parallel to the original path of the trace, and a third segment at the opposite 45 degree angle from the path of the trace. The distance between the trace 410B and the second segment of the serpentine curve of the trace 410A is referred to as the segment extent. The segment extent is the sum of the intra-pair spacing and an additional offset of the serpentine curve. In some example embodiments, the additional offset is less than or equal to the intra-pair spacing. The segment extent may be twice the intra-pair spacing.

The shape of the fin 420 may be defined by an extrusion clearance, an extrusion angle, an extrusion width, an extrusion height, or any suitable combination thereof. The extrusion clearance is the distance between the edge of the extrusion where it connects to the serpentine curve and the junction between the parallel segment and an angled segment of the serpentine curve. As shown in FIG. 2, the extrusion clearance is zero, since the upper-right and upper-left corners of the fin 420 are at the points where the parallel segment of the serpentine curve meets the angled portions of the serpentine curve. In other example embodiments, the extrusion clearance is one-quarter of the intra-pair spacing, one-half of the intra-pair spacing, 1.0 mil, or 2.0 mils.

The extrusion angle measures the angle between the parallel segment of the serpentine portion and the edge of the extrusion. In the example of FIG. 4, the extrusion angle is approximately 135 degrees. A completely absent extrusion would have an extrusion angle of 180 degrees. A fin is an extrusion with an extrusion angle greater than 90 degrees and less than 180 degrees (no extrusion). The extrusion width measures the width of the extrusion at its narrowest point. The extrusion width may be zero, in which case the extrusion is a triangle. The extrusion width may be less than, equal to, or greater than the intra-pair spacing. The extrusion height measures the distance to which the extrusion extends from the serpentine curve. The extrusion height may be less than or equal to the additional offset of the segment extent.

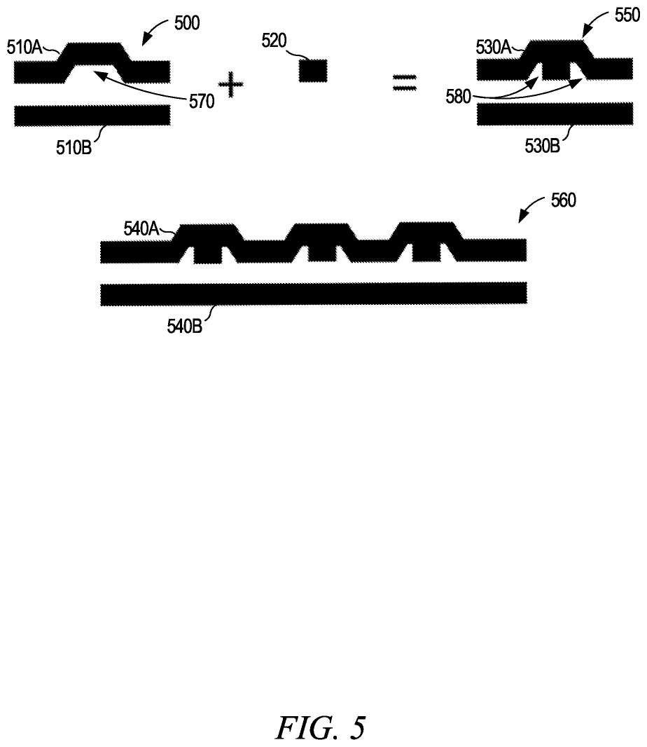

FIG. 5 depicts adding tabs to a serpentine section of a differential signal trace 560, according to some example embodiments. The differential signal trace 500 comprises traces 510A and 510B. The differential signal trace 550 comprises traces 530A and 530B. The differential signal trace 560 comprises traces 540A and 540B.

The trace 510A comprises a single serpentine curve with interior 570. A tab 520 may be added to the serpentine curve to form the serpentine curve with a tab extrusion of the trace 530A. The conductive path between the opposite sides of the serpentine curve is not shortened because of the presence of cutouts 580. The trace 540A includes a serpentine section with three serpentine curves. Each of the three serpentine curves of the trace 540A includes a tab extrusion. By virtue of the addition of the tab 520 to the interiors of the serpentine curves of the serpentine section of the trace 540A, the electrical properties, including impedance discontinuity and reflections, of the differential signal trace 560 are modified.

The shape of the tab may be defined by the same parameters as for a fin, as discussed above with respect to FIG. 4. A tab is an extrusion with an extrusion angle of 90 degrees.

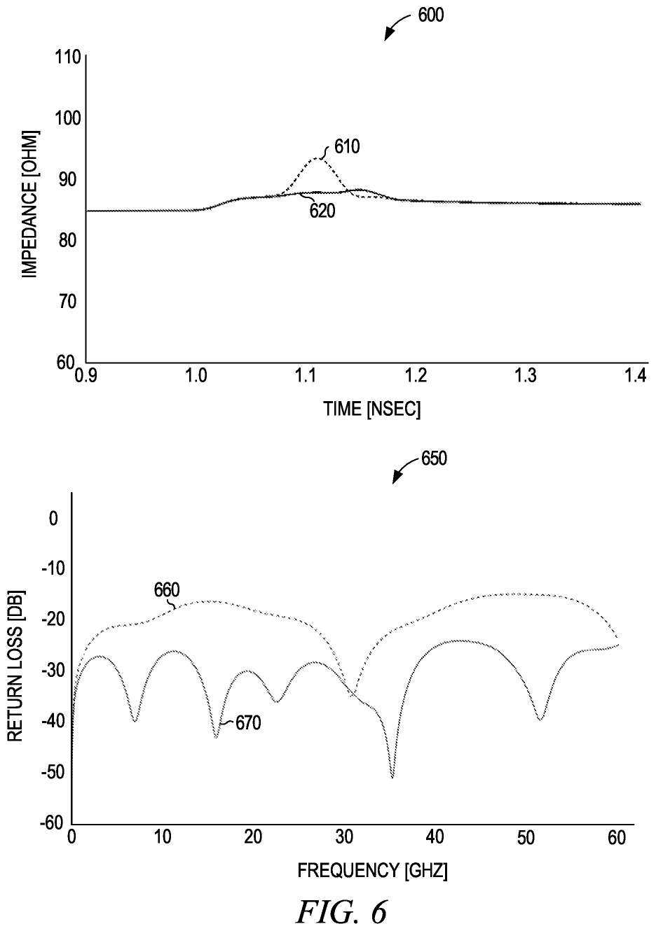

FIG. 6 shows differences in impedance for two different designs of differential traces, according to some example embodiments. The graph 600 shows the impedance, measured in Ohms, for each design as a function of time measured after the application of a step input. The graph 650 shows the return loss of a signal provided to the ball grid array (BGA) side of an FCBGA chip, measured in decibels, for each design as a function of frequency. The curves 610 and 660 represent the first design in the graphs 600 and 650 respectively. The curves 620 and 670 represent the second design in the graphs 600 and 650 respectively. The first design uses differential traces without extrusions. The second design uses differential traces with extrusions. The graphs 600 and 650 may be generated using software simulation of the two designs or by measuring the actual response of fabricated devices (e.g., using an oscilloscope).

The graph 600 shows that both designs have very similar impedances, of about 85 Ohms, for the time period before about 1.08 nanoseconds and after about 1.2 nanoseconds. However, between about 1.08 nanoseconds and 1.2 nanoseconds, the impedance of the first design spikes to about 93 Ohms. The variation in the impedance of the second design is much smaller. Thus, by virtue of the addition of extrusions to the serpentine portions, the deviation from the steady-state impedance is reduced for the second circuit design by comparison with the first.

The graph 650 shows that the first design has higher signal return losses than the second design at every frequency in the 0-60 GHz range except for a very small range near 30 GHz. Additionally, the minimum signal return loss of the second design of about-50 dB near 35 GHz is much less than the minimum signal return loss of the first design of about −35 dB near 30 GHz. Thus, by virtue of the addition of extrusions to the serpentine portions in the second design, the return loss is reduced and thus leading to lower reflections. By selecting whether to use fins or tabs and whether to include extrusions in some serpentine curves or all serpentine curves, the shape of the curves 620 and 670 may be modified for specific applications.

By comparison of the curves 610 and 620 of the graph 600 and comparison of the curves 660 and 670 of the graph 650, a circuit designer is enabled to select a circuit having matched impedance, less impedance variation over time, lower return loss corresponding to lower reflections, or any suitable combination thereof. In some example embodiments, circuit design software automatically selects a circuit design based on one or more of these criteria.

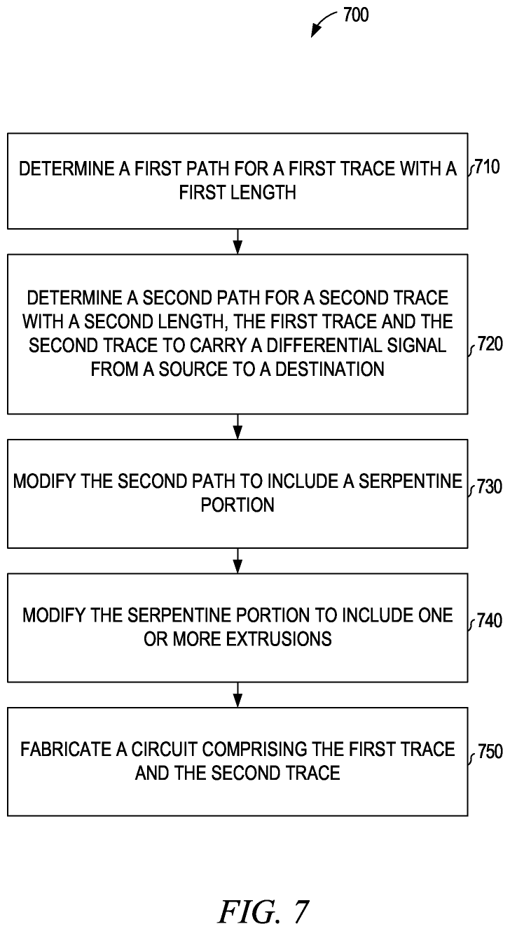

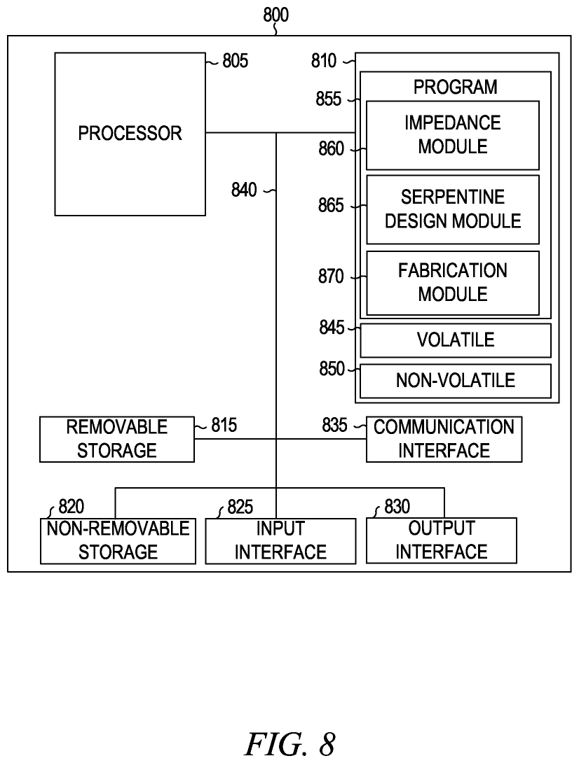

FIG. 7 is a flowchart of a method 700 of fabricating a circuit including a differential trace with a serpentine portion with extrusions, according to some example embodiments. The method 700 includes operations 710, 720, 730, 740, and 750. By way of example and not limitation, the method 700 is described as being performed by components of the system 800 of FIG. 8, with reference to the structures of FIGS. 1-5.

In operation 710, a serpentine design module 865 determines, in a circuit design, a first path for a first trace with a first length. The serpentine design module 865 also determines, in the circuit design, a second path for a second trace with a second length, the first trace and the second trace to carry a differential signal from a source to a destination (operation 720). For example, a circuit design may include a differential VIA that connects a first layer of a multi-layer circuit (e.g., layer 310A of FIG. 3) to a second layer of the multi-layer circuit (e.g., layer 310D) and the differential signal may be carried (once the circuit is fabricated) by the first and second traces from the differential VIA to a circuit component on the second layer. The first and second paths may be similar, but the first and second lengths may not be equal.

The serpentine design module 865 modifies the second path in the circuit design to include a serpentine portion (operation 730). For example, based on a difference between the first and second lengths, one or more serpentine curves may be added to the second path to increase the length of the second path so that the length of the modified second trace is equal to the length of the first trace. As a result, the intra-pair skew is reduced. Thus, the serpentine portion is configured to de-skew the differential signal, in some example embodiments.

In operation 740, the serpentine design module 865 modifies the serpentine portion to include one or more extrusions. For example, an impedance module 860 may determine an impedance for the differential trace without extrusions, with fins, with tabs, or any suitable combination thereof. As an example of a combination of elements, one or more serpentine curves may have extrusions while one or more serpentine curves do not. Additionally, one or more of the serpentine curves with extrusions may have fins while one or more other serpentine curves with extrusions have tabs. The combination that has the lowest impedance, the most consistent impedance over time, a frequency response with lower return loss leading to lower reflections, or any suitable combination thereof is chosen to be used for the modification. Thus, in some example embodiments, the one or more extrusions are configured to smooth an time-dependent impedance, reduce a maximum impedance in an operating frequency range, reduce a minimum impedance at a target operating frequency, or any suitable combination thereof.

After operations 710-740 are complete, a circuit design comprising the first trace and the second trace has been prepared. In operation 750, a fabrication module 870 fabricates, based on the circuit design, a circuit comprising the first trace and the second trace. Thus, by use of the method 700, multiple options for a differential trace are considered and the design with better impedance characteristics is fabricated.

FIG. 8 is a block diagram illustrating components of a system 800 for performing the methods described herein, according to some example embodiments. All components need not be used in various embodiments. For example, clients, servers, autonomous systems, and cloud-based network resources may each use a different set of components, or, in the case of servers, for example, larger storage devices.

One example computing device in the form of a computer 800 (also referred to as computing device 800 and computer system 800) may include a processor 805, memory storage 810, removable storage 815, and non-removable storage 820, all connected by a bus 840. Although the example computing device is illustrated and described as the computer 800, the computing device may be in different forms in different embodiments. For example, the computing device may instead be a smartphone, a tablet, a smartwatch, or another computing device including elements the same as or similar to those illustrated and described with regard to FIG. 8. Devices such as smartphones, tablets, and smartwatches are collectively referred to as “mobile devices.” Further, although the various data storage elements are illustrated as part of the computer 800, the storage may also or alternatively include cloud-based storage accessible via a network, such as the Internet, or server-based storage.

The memory storage 810 may include volatile memory 845 and non-volatile memory 850 and may store a program 855. The computer 800 may include, or have access to, a computing environment that includes a variety of computer-readable media, such as the volatile memory 845; the non-volatile memory 850; the removable storage 815; and the non-removable storage 820. Computer storage includes random-access memory (RAM), read-only memory (ROM), erasable programmable read-only memory (EPROM) and electrically erasable programmable read-only memory (EEPROM), flash memory or other memory technologies, compact disc read-only memory (CD-ROM), digital versatile disks (DVDs) or other optical disk storage, magnetic cassettes, magnetic tape, magnetic disk storage or other magnetic storage devices, or any other medium capable of storing computer-readable instructions.

The computer 800 may include or have access to a computing environment that includes an input interface 825, an output interface 830, and a communication interface 835. The output interface 830 may interface to or include a display device, such as a touchscreen, that also may serve as an input device. The input interface 825 may interface to or include one or more of a touchscreen, a touchpad, a mouse, a keyboard, a camera, one or more device-specific buttons, one or more sensors integrated within or coupled via wired or wireless data connections to the computer 800, and other input devices. The computer 800 may operate in a networked environment using the communication interface 835 to connect to one or more remote computers, such as database servers. The remote computer may include a personal computer (PC), server, router, network PC, peer device or other common network node, or the like. The communication interface 835 may connect to a local-area network (LAN), a wide-area network (WAN), a cellular network, a WiFi network, a Bluetooth network, or other networks.

Computer instructions stored on a computer-readable medium (e.g., the program 855 stored in the memory storage 810) are executable by the processor 805 of the computer 800. A hard drive, CD-ROM, and RAM are some examples of articles including a non-transitory computer-readable medium such as a storage device. The terms “computer-readable medium” and “storage device” do not include carrier waves to the extent that carrier waves are deemed too transitory. “Computer-readable non-transitory media” includes all types of computer-readable media, including magnetic storage media, optical storage media, flash media, and solid-state storage media. It should be understood that software can be installed in and sold with a computer. Alternatively, the software can be obtained and loaded into the computer, including obtaining the software through a physical medium or distribution system, including, for example, from a server owned by the software creator or from a server not owned but used by the software creator. The software can be stored on a server for distribution over the Internet, for example.

The program 855 is shown as including an impedance module 860, a serpentine design module 865, and a fabrication module 870. Any one or more of the modules described herein may be implemented using hardware (e.g., a processor of a machine, an application-specific integrated circuit (ASIC), a field programmable gate array (FPGA), or any suitable combination thereof). Moreover, any two or more of these modules may be combined into a single module, and the functions described herein for a single module may be subdivided among multiple modules. Furthermore, according to various example embodiments, modules described herein as being implemented within a single machine, database, or device may be distributed across multiple machines, databases, or devices.

The impedance module 860 determines the impedance of a differential trace for a circuit design. By comparing the results for different designs, the serpentine design module 865 selects a design having reduced reflections and a better impedance profile for fabrication. The fabrication module 870 controls photolithographic and chemical processing steps, computerized numerical control (CNC) machines, and other devices to fabricate multi-layer circuits.

### EXAMPLES

Example 1 is a circuit comprising: a first trace having a serpentine portion with one or more extrusions; and a second trace configured to carry, with the first trace, a differential signal.

In Example 2, the subject matter of Example 1, wherein the one or more extrusions comprise a tab.

In Example 3, the subject matter of Examples 1-2, wherein the one or more extrusions comprise a fin.

In Example 4, the subject matter of Examples 1-3, wherein the serpentine portion is configured to de-skew the differential signal.

In Example 5, the subject matter of Examples 1-4, wherein the one or more extrusions are configured to reduce a deviation from a steady-state impedance in response to a step function input for the differential signal.

In Example 6, the subject matter of Examples 1-5, wherein the one or more extrusions are configured to reduce, in an operating frequency range, a maximum impedance of a differential trace comprising the first trace and the second trace.

In Example 7, the subject matter of Examples 1-6, wherein the one or more extrusions are configured to reduce, at a target operating frequency, a minimum impedance of a differential trace comprising the first trace and the second trace.

In Example 8, the subject matter of Examples 1-7, embedded in a printed circuit board.

In Example 9, the subject matter of Examples 1-8, embedded in a cable.

In Example 10, the subject matter of Examples 1-9, wherein: the circuit is a multi-layer circuit; and the first trace and the second trace receive the differential signal from a differential vertical interconnect access (VIA) connecting two layers of the multi-layer circuit.

Example 11 is a method comprising: determining a first path for a first trace with a first length; determining a second path for a second trace with a second length, the first trace and the second trace to carry a differential signal from a source to a destination; modifying the second path to include, a serpentine portion; modifying the serpentine portion to include one or more extrusions; and fabricating a circuit comprising the first trace and the second trace.

In Example 12, the subject matter of Example 11, wherein the one or more extrusions comprise a tab.

In Example 13, the subject matter of Examples 11-12, wherein the one or more extrusions comprise a fin.

In Example 14, the subject matter of Examples 11-13, wherein the modifying of the second path to include the serpentine portion is based on a difference between the first length and the second length.

In Example 15, the subject matter of Examples 11-14, wherein the modifying of the serpentine portion to include the one or more extrusions is based on an impedance of the modified second path.

In Example 16, the subject matter of Examples 11-15 includes configuring the one or more extrusions to reduce, in an operating frequency range, a maximum impedance of a differential trace comprising the first trace and the second trace.

In Example 17, the subject matter of Examples 11-16 includes configuring the one or more extrusions to reduce, at a target operating frequency, a minimum impedance of a differential trace comprising the first trace and the second trace.

In Example 18, the subject matter of Examples 11-17, wherein the fabricating of the circuit comprises embedding the circuit in a printed circuit board.

In Example 19, the subject matter of Examples 11-18, wherein the fabricating of the circuit comprises embedding the circuit in a cable.

In Example 20, the subject matter of Examples 11-19, wherein: the circuit is a multi-layer circuit; and the first trace and the second trace receive the differential signal from a differential vertical interconnect access (VIA) connecting two layers of the multi-layer circuit.

Example 21 is at least one machine-readable medium including instructions that, when executed by processing circuitry, cause the processing circuitry to perform operations to implement of any of Examples 1-20.

Example 22 is an apparatus comprising means to implement any of Examples 1-20.

Example 23 is a system to implement any of Examples 1-20.

Example 24 is a method to implement any of Examples 1-20.

The Abstract of the Disclosure is provided to comply with 37 C.F.R. § 1.72(b), requiring an abstract that allows the reader to quickly ascertain the nature of the technical disclosure. It is submitted with the understanding that it will not be used to interpret or limit the claims. In addition, in the foregoing Detailed Description, it may be seen that various features are grouped together in a single embodiment for the purpose of streamlining the disclosure. This method of disclosure is not to be interpreted as limiting the claims. Thus, the following claims are hereby incorporated into the Detailed Description, with each claim standing on its own as a separate embodiment.

What is claimed is:

1. A circuit comprising:
a first trace having a serpentine portion with one or more extrusions; and
a second trace configured to carry, with the first trace, a differential signal.

2. The circuit of claim 1, wherein the one or more extrusions comprise a tab.

3. The circuit of claim 1, wherein the one or more extrusions comprise a fin.

4. The circuit of claim 1, wherein the serpentine portion is configured to de-skew the differential signal.

5. The circuit of claim 1, wherein the one or more extrusions are configured to reduce a deviation from a steady-state impedance in response to a step function input for the differential signal.

6. The circuit of claim 1, wherein the one or more extrusions are configured to reduce, in an operating frequency range, a maximum impedance of a differential trace comprising the first trace and the second trace.

7. The circuit of claim 1, wherein the one or more extrusions are configured to reduce, at a target operating frequency, a minimum impedance of a differential trace comprising the first trace and the second trace.

8. The circuit of claim 1, embedded in a printed circuit board.

9. The circuit of claim 1, embedded in a cable.

10. The circuit of claim 1, wherein:
the circuit is a multi-layer circuit; and
the first trace and the second trace receive the differential signal from a differential vertical interconnect access (VIA) connecting two layers of the multi-layer circuit.

11. A method comprising:
determining a first path for a first trace with a first length;
determining a second path for a second trace with a second length, the first trace and the second trace to carry a differential signal from a source to a destination;
modifying the second path to include a serpentine portion;
modifying the serpentine portion to include one or more extrusions; and
fabricating a circuit comprising the first trace and the second trace.

12. The method of claim 11, wherein the one or more extrusions comprise a tab.

13. The method of claim 11, wherein the one or more extrusions comprise a fin.

14. The method of claim 11, wherein the modifying of the second path to include the serpentine portion is based on a difference between the first length and the second length.

15. The method of claim 11, wherein the modifying of the serpentine portion to include the one or more extrusions is based on an impedance of the modified second path.

16. The method of claim 11, further comprising configuring the one or more extrusions to reduce, in an operating frequency range, a maximum impedance of a differential trace comprising the first trace and the second trace.

17. The method of claim 11, further comprising configuring the one or more extrusions to reduce, at a target operating frequency, a minimum impedance of a differential trace comprising the first trace and the second trace.

18. The method of claim 11, wherein the fabricating of the circuit comprises embedding the circuit in a printed circuit board.

19. The method of claim 11, wherein the fabricating of the circuit comprises embedding the circuit in a cable.

20. The method of claim 11, wherein:
the circuit is a multi-layer circuit; and
the first trace and the second trace receive the differential signal from a differential vertical interconnect access (VIA) connecting two layers of the multi-layer circuit.
